(19) United States
(12) Patent Application Publication
(10) Pub. No.: US 2014/0138727 A1
(43) Pub. Date: May 22, 2014

(54) METHOD AND APPARATUS FOR PROCESSING A WORKPIECE AND AN ARTICLE FORMED THEREBY

(71) Applicant: Electro Scientific Industries, Inc., Portland, OR (US)

(72) Inventors: THOMAS CHANG, Mountain View, CA (US); THOMAS BOATWRIGHT, San Jose, CA (US); JONATHAN D. HALDERMAN, SUNNYVALE, CA (US)

(73) Assignee: Electro Scientific Industries, Inc., Portland, OR (US)

(21) Appl. No.: 14/080,636

(22) Filed: Nov. 14, 2013

Related U.S. Application Data
(60) Provisional application No. 61/727,606, filed on Nov. 16, 2012.

(51) Int. Cl. H01L 33/00; H01L 33/54

(52) U.S. Cl. CPC H01L 33/005; H01L 33/54
USPC 257/98; 438/33; 257/100

(57) ABSTRACT

A manufacturing process is applicable to singulating die from a substrate, where the substrate has a layer distinguishable from the substrate by a mechanical property such as brittleness. The process can include providing a workpiece including a substrate and a layer disposed on a first surface, modifying the mechanical property such as by compression, deforming a region of the substrate proximate to the portion of the layer having the modified mechanical property; and fracturing the portion of the layer at a location proximate to the deformed region of the substrate. Also, the process can include propagating a crack through a region of the substrate on a line along the modified portion of the layer. A die formed in this manner is also provided.

### RELATED APPLICATIONS

This application claims the benefit of U.S. provisional patent application Ser. No. 61/727,606 filed on 16 Nov. 2012, which application is incorporated by reference as if fully set forth herein.

### BACKGROUND

Embodiments of the present invention exemplarily described herein relate generally to methods and apparatus for processing workpieces. More particularly, embodiments of the present invention relate to methods and apparatus for cutting layers. Even more particularly, embodiments of the present invention relate to methods and apparatus for separating a component package (e.g., containing one or more semiconductor devices, light-emitting diodes (LEDs), micro-electromechanical systems, or the like or a combination thereof) from a package substrate by fracturing multiple layers formed of dissimilar materials.

In a typical component packaging process, one or more dies (e.g., each including one or more previously-fabricated objects such as semiconductor devices, light-emitting diodes, micro-electromechanical systems, and the like), are attached to a common substrate or frame (generically referred to herein as a “package substrate”), electrical connections are made between the dies and external contact areas or leads on the package substrate, and one or more functional materials (e.g., for providing heat conduction, stress relief, and protection from moisture, dust, light, physical shock, etc., or the like or a combination thereof), are applied to the dies and the package substrate, thereby forming a die-package substrate assembly. Thereafter, the die-package substrate assembly is subjected to a singulation process in which the package substrate and one or more functional materials are cut (e.g., along one or more scribe lines within the die-package substrate assembly, which extend between adjacent dies disposed on the package substrate) so that individual packages may be separated from each other. Conventionally, singulation processes are performed using a mechanical saw which rips, gouges and tears to remove one or more materials located within the scribe line of the die-package substrate assembly. Use of such saws, however, can be undesirable due to particulate debris generated during the sawing process, because the saws wear and need to be replaced frequently, and because the sawing process is relatively slow. Further, conventional saw blades require a kerf width (e.g., space between adjacent dies) between about 100 μm and 150 μm. This large kerf width requirement makes it difficult to minimize the spacing between adjacent dies on the package substrate and thereby increase the number of component packages that can be singulated from a single die-package substrate assembly. Additionally, water or other lubricants typically need to be applied to the saw blade during the singulation process. Laser-based singulation techniques, which use laser light to remove various materials by ablation, have been developed to address shortcomings of mechanical saws for singulation. Nevertheless, the lasers can undesirably degrade one or more functional materials during the singulation process and can undesirably generate particulate debris. An alternative laser singulation process involves focusing a laser beam to form internal cracks within the substrate. Thereafter, the substrate can be broken along a scribe line formed by the internal cracks. While this alternative laser singulation technique can effectively prevent the generation of particulate debris, it is incapable of cutting through layers that are formed on the substrate and, therefore, is not suitable for singulation of component packages from a die-package substrate assembly.

### BRIEF DESCRIPTION OF THE DRAWINGS

FIG. 1 is a side plan view schematically illustrating a die-package substrate assembly according to one embodiment.

FIG. 2 is a schematic view illustrating one embodiment of an apparatus for singulating a component package from the die-package substrate assembly shown in FIG. 1.

FIG. 3 is a side plan view schematically illustrating one embodiment of a process for singulating a component package from a die-package substrate assembly using the apparatus shown in FIG. 2.

FIG. 4 is a side plan view schematically illustrating one embodiment of a component package singulated in the process shown in FIG. 3.

### DETAILED DESCRIPTION OF THE ILLUSTRATED EMBODIMENTS

The following embodiments are described in sufficient detail to enable those skilled in the art to make and use the invention. It is to be understood that other embodiments would be evident based on the present disclosure, and that process or mechanical changes may be made without departing from the scope of the present invention defined in the claims. In the following description, numerous specific details are given to provide a thorough understanding of the invention. However, it will be apparent that the invention may be practiced without these specific details. In order to avoid obscuring the present invention, some well-known system configurations and process steps are not disclosed in detail. Likewise, the drawings showing embodiments of the system are schematic and not to scale and, particularly, some of the dimensions are for the clarity of presentation and are shown greatly exaggerated in the drawings. Unless otherwise specified, a range of values, when recited, includes both the upper and lower limits of the range, as well as any sub-ranges therebetween. In addition, where multiple embodiments are disclosed and described having some features in common, for clarity and ease of illustration, description, and comprehension thereof, similar and like features one to another will ordinarily be described with like reference numerals.

Generally, embodiments of the present invention can be broadly characterized as relating to the fracture of a layer (e.g., upon the action of stress) that is supported on a substrate. In some embodiments, the layer may be fractured by a process that includes altering the portion of the layer, deforming a region of the substrate proximate to the portion of the layer and fracturing the portion of the layer at a location proximate to the deformed region of the substrate. In another embodiment, however, the layer may be fractured without altering the portion of the layer. The fracturing described herein can be performed in a manner that results in little or no material removal from the portion of the layer. Such a fracturing process can be characterized as a cracking process, a splitting process, a parting process, and the like.

The substrate may include at least one object located on the first surface, the at least one object such as a semiconductor device (e.g., including at least one device such as a laser diode, a light-emitting diode, a field effect transistor, an integrated circuit, a micro-processor, a hall-effect sensor, a charge-coupled device, a random-access memory or the like or a combination thereof), a micro-electro-mechanical system (MEMS) (e.g., including at least one device such as a pressure sensor, an accelerometer, a gyroscope, a microphone, a digital mirror array, or the like or a combination thereof), a microfluidic device (e.g., including at least one device such as a continuous-flow device, a lab-on-chip device configured to manipulate fluid by means of surface acoustic waves, optoelectrowetting, mechanical actuation, etc., a microarray device, a tunable microlens array, or the like or a combination thereof), or the like or a combination thereof.

Generally, an area of the substrate surrounding the aforementioned region may have a thickness, measured from the first surface to a second surface opposite the first surface, which is in a range from 300 μm to 1000 μm. In other embodiments, however, the thickness may be less than 300 μm or greater than 1000 μm. The substrate may be provided as a semiconductor substrate (e.g., including at least one material such as silicon, silicon carbide, silicon-germanium alloy, gallium nitride, gallium arsenide, indium gallium nitride, aluminum gallium arsenide, indium phosphide, zinc selenide, or the like or a combination thereof), a ceramic substrate (e.g., a sintered ceramic substrate including at least one material such as alumina, aluminum nitride, or the like or a combination thereof), a glass substrate (e.g., including at least one material such as soda-lime glass, borosilicate glass, aluminosilicate glass, aluminoborosilicate glass, sodium-aluminosilicate glass, calcium-aluminosilicate glass, phosphate glass, fluoride glass, chalcogenide glass, bulk metallic glass, or the like or a combination thereof), a metallic substrate (e.g., including at least one material such as aluminum, cobalt, copper, iron, magnesium, nickel, palladium, titanium, tungsten, zinc, or the like or a combination thereof), a diamond substrate, a polymeric substrate, or the like or a combination thereof. In some embodiments, the substrate may be may be provided as a package substrate used in the fabrication of component packages containing one or more semiconductor devices, MEMS devices, microfluidic devices, or the like or a combination thereof.

Generally, the portion of the layer is bonded to the substrate, either directly or indirectly (e.g., via an intervening adhesive material between the layer and the substrate) such that the portion of the layer cannot be removed from the substrate without first degrading the layer, the substrate, or the adhesive material therebetween. Thus, the portion of the layer may physically contact the substrate, or may be spaced apart from the substrate. In other embodiments, however, the portion of the layer is not bonded to the substrate. In one embodiment, the layer may extend over the at least one object, and physically contact the at least one object or be spaced apart therefrom. In one embodiment, the portion of the layer may have a thickness in a range from 1 μm to 300 μm. For example, the portion of the layer may have a thickness that is less than 200 μm, less than 150 μm, less than 100 μm, or less than 50 μm. In other embodiments, however, the thickness of the portion of the layer may be less than 1 μm or greater than 300 μm.

In one embodiment, the layer is formed of a single material. Thus, the portion of the layer may also be formed of a single material such as any suitable, desired or beneficial thermoplastic, thermoset, or elastomeric material (e.g., including a polymeric material such as polyimide, polyurethane, silicone, polymethyl methacrylate, polycarbonate, epoxy, or the like or a combination thereof), metallic material (e.g., including at least one material such as aluminum, cobalt, copper, iron, magnesium, nickel, palladium, titanium, tungsten, zinc, or the like or a combination thereof), glass material (e.g., including at least one material such as soda-lime glass, borosilicate glass, aluminosilicate glass, aluminoborosilicate glass, sodium-aluminosilicate glass, calcium-aluminosilicate glass, phosphate glass, fluoride glass, chalcogenide glass, bulk metallic glass, or the like or a combination thereof), ceramic material, or the like or a combination thereof. In embodiments in which the layer is formed of a metallic material, the metallic material may have at least one metallic constituent having a body-centered-cubic (BCC) or hexagonal-close-packed (HCP) crystal structure, although embodiments of the present invention may also be implemented with the layer includes a metallic constituent having a face-centered-cubic (FCC) crystal structure. In another embodiment, the layer is formed of as a multilayer structure formed of distinct layers materials, as a single-layer structure having a graded material composition, or the like or a combination thereof. It will be appreciated that the material(s) from which the portion of the layer is formed may be different from the material(s) from which the substrate is formed. In some embodiments, the portion of the layer may be may be provided as a conductive trace, an electrode, a wavelength-conversion layer, a stress relief layer, a moisture barrier, a light barrier, a dust barrier, a shock barrier, or the like or a combination thereof, that may be present in component packages containing one or more semiconductor devices, MEMS devices, microfluidic devices, or the like or a combination thereof.

Constructed as exemplarily described above, the substrate, the at least one object, and the layer can form a die-package substrate assembly in which one or more plurality of dies (e.g., each including one or more of the aforementioned objects), are attached to the substrate. If more than one die is attached to the substrate, the dies can be spaced apart from each other along one or more scribe lines. In one embodiment, the portion of the layer can be altered to facilitate singulation of one or more component packages from a die-package substrate assembly.

Generally, the portion of the layer can be characterized as having a mechanical property (e.g., including yield strength, ultimate tensile strength, ultimate compressive strength, elasticity, rigidity, plasticity, malleability, brittleness, hardness, resilience, toughness, or the like or a combination thereof). Accordingly, the portion of the layer can be altered by modifying the preliminary mechanical property of the portion of the layer. In one embodiment, modifying the mechanical property of the portion of the layer can involve decreasing the ductility or malleability of the portion of the layer. The ductility or malleability of the portion of the layer may be decreased in any suitable, desired or beneficial manner. For example, the ductility or malleability of the portion of the layer can be decreased by cooling the portion of the layer (e.g., to a temperature of less than 10° C., less than 5° C., less than 0° C. or, in terms of material properties, at or below a glass-transition temperature or other ductile-to-brittle transition temperature of the material forming the portion of the layer). It will be appreciated that the degree of cooling necessary to decrease the ductility or malleability of the portion of the layer can depend upon factors such as the composition of the layer, the molecular or crystalline structure of the portion of the layer, the thickness of the portion of the layer, the desired decrease in ductility or malleability, the rate at which a mechanical load might be applied to the portion of the layer, or the like or a combination thereof. In another example, a mechanical force (e.g., compressive, tensile, torsional, or shear, or the like or a combination thereof) can be applied to the portion of the layer to deform the portion of the layer at a sufficiently high strain rate to modify a mechanical property (e.g., decrease the ductility or malleability) of the portion of the layer. It will be appreciated that the strain rate necessary to decrease the ductility or malleability of the portion of the layer can depend upon factors such as the composition of the layer, the thickness of the portion of the layer, the temperature of the portion of the layer, the molecular or crystalline structure of the portion of the layer, the desired decrease in ductility or malleability, and the like. In another embodiment, modifying the mechanical property of the portion of the layer can involve increasing the ductility or malleability of the portion of the layer, or alternately decreasing and increasing the ductility or malleability of the portion of the layer (or vice-versa). The ductility or malleability of the portion of the layer may be increased in any suitable, desired or beneficial manner (e.g., by heating the portion of the layer). In yet another embodiment, the portion of the layer can be altered by applying a mechanical force (e.g., compressive, tensile, torsional, or shear, or the like or a combination thereof) to the portion of the layer to compressing the portion of the layer at a sufficiently low strain rate that does not modify a mechanical property (e.g., the ductility or malleability) of the portion of the layer. The applied mechanical force may, by itself, result in the portion of the layer being compressed, stretched, or the like or a combination thereof. In one embodiment, such a mechanical force may be applied by pressing the portion of the layer with an object such as a chisel, blade, a hammer, a punch, or the like or a combination thereof, against the substrate. The object may be structured, and the force may be applied from the object to the portion of the layer, such that the portion of the layer is at least partially fractured, or not fractured at all, upon application of the mechanical force to the portion of the layer.

Generally, the region of the substrate is deformed to facilitate singulation of one or more component packages from a die-package substrate assembly. For example, the region of the substrate can be deformed by stretching the region of the substrate, compressing the region of the substrate, by twisting the region of the substrate, by bending the region of the substrate, or the like or a combination thereof. In one embodiment, the region of the substrate can be deformed so as to propagate one or more cracks within the region of the substrate to the first surface of the substrate at a location generally aligned with one or more corresponding scribe lines of the die-package substrate assembly. Thus, the portion of the layer having the modified mechanical property is located within a region of the die-package substrate assembly occupied by one or more scribe lines.

In one embodiment, the substrate may be processed prior to being deformed to facilitate generation and/or propagation of the crack. For example, the substrate may be processed to form one or more crack initiators (e.g., one or more voids, dislocations, color centers, grain boundaries, micro-cracks, or the like or a combination thereof). The crack initiator may be located at the second surface of the substrate, or may be spaced apart from the second surface of the substrate. In embodiments in which the crack initiator is spaced apart from the second surface, the crack initiator may be located wholly within bulk material of the substrate, at a machined surface (e.g., of a trench, groove, or the like) located elevationally between the first surface and the second surface, or the like or a combination thereof. The crack initiator may also extend along a straight or curved line within the substrate so that a crack propagating therefrom can be fractured at least substantially along the line.

The crack initiator may be formed by any suitable, desired or beneficial method. For example, the crack initiator may be formed by machining the second surface (e.g., grinding, cutting, abrading, etching, ablating, or the like or a combination thereof), to form a groove extending into the substrate. In such an embodiment, the groove may terminate at a tip within the bulk material of the substrate functioning as a stress-concentrator from which a crack may propagate in the presence of an applied stress (e.g., a bending moment applied in the vicinity of the groove). In another embodiment, crack initiator may be formed by altering one or more characteristics of the substrate (e.g., density, material composition, molecular geometry, crystal structure, electronic structure, microstructure, nanostructure, or the like or a combination thereof) to form an altered substrate region present at the second surface, between the first and second surfaces, or a combination thereof. The altered region can function as a stress-concentrator from which a crack may propagate in the presence of an applied stress (e.g., a bending moment applied in the vicinity of the altered region).

In one embodiment, the crack initiator (e.g., whether formed by machining the second surface or by forming the altered region) may be formed by directing at least one laser pulse onto substrate (e.g., from the first surface, from the second surface, or a combination thereof). It will be appreciated that characteristics of the at least one laser pulse (e.g., pulse wavelength, pulse duration, average power, peak power, spot fluence, scan rate, pulse repetition rate, spot shape, spot diameter, or the like or a combination thereof), can be selected as desired or appropriate to form a crack initiator. For example, the pulse wavelength can be in the ultra violet range, visible range, or infrared range of the electromagnetic spectrum (e.g., in a range from 238 nm to 10.6 μm, such as 343 nm, 355 nm, 532 nm, 1030 nm, 1064 nm, or the like). Exemplary laser-based methods by which the crack initiator may be formed are discussed in U.S. Pat. No. 7,241,669, International Patent Publication No. WO 2012/006736, U.S. Patent App. Pub. No. 2012/0175652, U.S. Patent App. Pub. No. 2012/0211477, the contents of all of which are incorporated herein by reference in their entirety.

Regardless of the manner in which the region of the substrate is deformed, the region of the substrate is deformed such that the altered portion of the layer becomes fractured. While not wishing to be bound by any particular theory, it is believed that the portion of the layer can become fractured due to a force imparted by the first surface of the substrate to the portion of the layer during the deformation of the region of the substrate, due to a force imparted by the first surface of the substrate to the portion of the layer after the deformation of the region of the substrate, due to a force imparted by a crack tip propagating from the crack initiator during the deformation of the region of the substrate, or the like or a combination thereof. To facilitate singulation of one or more component packages from a die-package substrate assembly, the fracture may extend completely through the thickness of the layer (e.g., along one or more scribe lines within the die-package substrate assembly). Alternatively, depending on factors such as the nature of the modified mechanical property, the thickness and composition of the portion of the layer, the nature of the deformation of the region of the substrate, and the like, the fracture may extend only partially through the thickness of the layer. Further depending on such factors such as the nature of the modified mechanical property, the thickness and composition of the portion of the layer, the nature of the deformation of the region of the substrate, and the like, the fracture can be characterized as a brittle fracture, as ductile fracture, or a combination of brittle and ductile fracture. Examples of brittle fracture that may occur within the portion of the layer having the modified mechanical property include cleavage fracture, (e.g., basal, cubic, octahedral, dodecahedral, rhomohedral, prismatic, etc.), parting, conchoidal fracture, and the like.

According to the embodiments exemplarily described above, the altered portion of the layer is fractured (either completely or partially) during deformation of the region of the substrate. In other embodiments, however, the portion of the layer having the modified stress-strain property may be at least partially fractured before the substrate is deformed. For example, the altered portion of the layer may be at least partially fractured before the substrate is deformed. In such an embodiment, the altered portion of the layer may be at least partially fractured due to, for example, a mechanical force (e.g., imparted by an external object such as a chisel, a razor blade, a hammer, a punch, or the like or a combination thereof). In still another embodiment, however, the portion of the layer may be at least partially fractured (e.g., before, during and/or after the substrate has been deformed) without first being altered. In such an embodiment, the portion of the layer may be split, parted, or the like (e.g., using a sharp knife or other blade) in a manner that results in no (or substantially no) material removal from the portion of the layer. Fracturing by splitting, parting, etc., can be performed along all or part of one or more scribe lines in the die-package substrate assembly (e.g., to facilitate singulation of one or more component packages from the die-package substrate assembly).

According to embodiments exemplarily described above, the methods described herein can be adapted to singulate die-package substrate packages at a higher throughput than the aforementioned techniques that involve the conventional use of mechanical saws or lasers, while also minimizing or preventing entirely the undesirable generation of particulate debris. Further, because mechanical saws are not required, the scribe lines within the die-package substrate assembly can be made narrower than 100 μm (e.g., less than 50 μm, less 20 μm, or even about 10 μm). Consequently, the methods described above enable more dies to be attached to a package substrate than conventional singulation techniques using mechanical saws permit. Having discussed exemplary embodiments of methods for fracturing materials in general, and for generally singulating a component package from a die-package substrate assembly, exemplarily embodiments of methods of singulating an LED package from a die-package substrate assembly, apparatus for performing these methods (e.g., for singulating the LED package from the die-package substrate assembly), and an article (e.g., an LED package) formed thereby, will now be described with reference to the following figures. It will nevertheless be appreciated, that the methods and apparatus described herein can be applied in any suitable, desired, or beneficial manner during the formation of any component package, or of any die capable of being included within a component package.

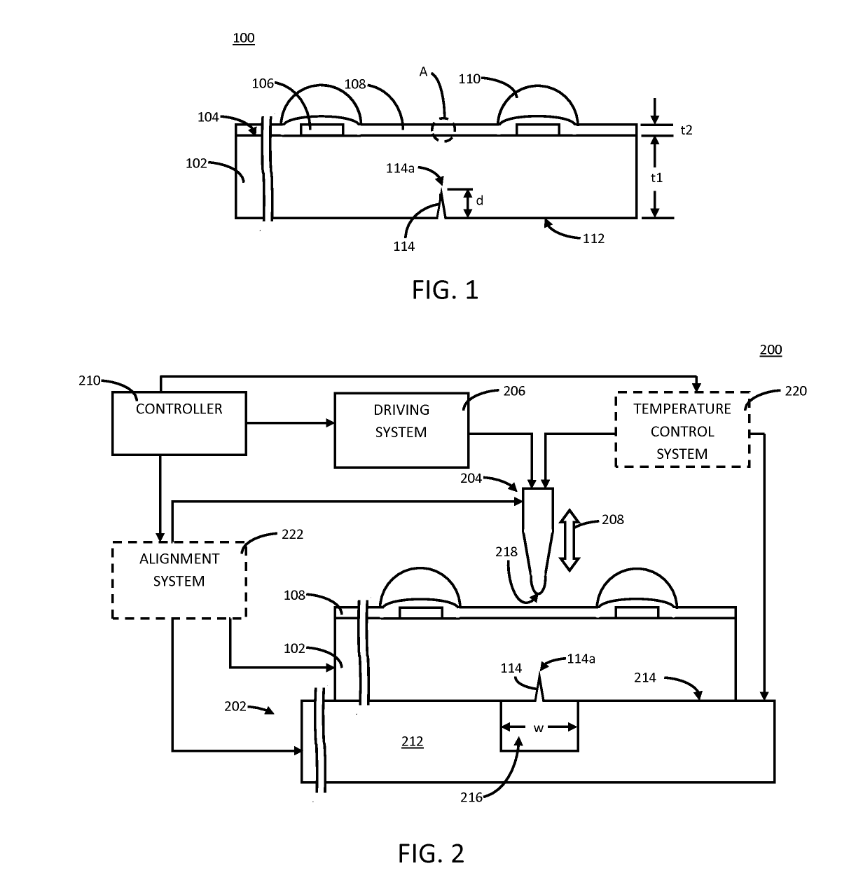

FIG. 1 is a side plan view schematically illustrating a die-package substrate assembly according to one embodiment.

Referring to FIG. 1, a die-package substrate assembly such as die-package substrate assembly 100 may include a package substrate such as substrate 102 having a first surface 104, a plurality of LED dies 106 disposed on the first surface 104 of the substrate 102, a layer 108 disposed on the first surface 104 of the substrate 102, and a plurality of lenses 110 disposed on the layer 108 over corresponding ones of the plurality of LED dies 106.

Generally, the substrate 102 is formed of a material having one or more beneficial characteristics such as good electrical insulation, high thermal conductivity, high flexural strength, chemical stability at high temperatures, ease with which it can be processed (e.g., ability to be suitably laser drilled, metallized, plated, brazed, or the like or a combination thereof), or the like or a combination thereof. Examples of materials from which the substrate 102 can be formed as a sintered ceramic substrate including alumina, aluminum nitride, and the like. The substrate 102 can have a thickness, t1, measured from the first surface 104 to a second surface 112 opposite thereto in a range from 300 μm to 1000 μm. As exemplarily illustrated, the second surface 112 of the substrate 102 has been machined to form a trench 114 extending from the second surface 112 into the substrate 102 toward the first surface 104 to a depth, d, which is in a range from about 5% to about 40% of the thickness t1 of the substrate 102. The trench 114 includes sidewalls that converge from the second surface 112 to a tip having a sharpness sufficient to serve as a crack initiator. Thus, a crack initiator 114a extends into the substrate 102 to a depth, d, that is elevationally between the first surface 104 and the second surface 112. It will nevertheless be appreciated that the crack initiator 114a may be formed by any suitable method as exemplarily described above.

Although not shown, each LED die 106 may include one or more LEDs formed on a carrier substrate. Generally, an LED may include an n-type doped semiconductor layer and a p-type doped semiconductor layer configured as a p-n junction designed to emit light during operation. An LED may further include a multiple quantum well (MQW) sandwiched in the PN junction for tuned characteristic and enhanced performance. Any LED die 106 may be provided as a horizontal LED (e.g., in which electrical connections for both the p and n junctions are made on the same side of the LED die), as a vertical LED die (e.g., in which electric current flows across the p-n junction through electrodes located on opposite sides of the LED die), or as an LED die having a hybrid configuration. Each LED die 106 may be attached to the package substrate 102 by an intervening die-attach adhesive, solder bumps, anisotropic conductive paste, or the like or a combination thereof. Although not shown, electrical connections between electrodes within each LED die 106 and electrodes, metallized traces, conductive through vias, etc., on the substrate 102 by electrically conductive structures such as wires, solder bumps (e.g., via flip-chip techniques), or the like or a combination thereof (not shown).

The layer 108 may be provided as an encapsulant layer formed of a material having one or more beneficial characteristics such high optical transparency in the UV to visible wavelength ranges, good photo-thermal stability, good moisture resistance, good adhesion to the substrate 102, or the like or a combination thereof. Examples of materials from which the layer 108 can be formed include silicone, epoxy, or the like or a combination thereof. In one embodiment, the layer 108 may also include one or more materials dispersed therein to scatter light emitted by an LED, absorb light emitted by an LED, convert absorbed light and emit light at another (e.g., longer) wavelength, or the like or a combination thereof. The layer 108 may be applied to the LED dies 106 and the first surface 104 of the substrate 102 by any suitable method (e.g., by printing, spraying, spin coating, or the like or a combination thereof), followed by a curing step. A portion of the layer 108 (e.g., portion enclosed in region “A”, disposed in a scribe line region between the two illustrated LED dies 106) can have a thickness, t2, that is less than 200 μm. For example, t2 can be less than 150 μm, less than 100 μm, or less than 50 μm. In other embodiments, however, t2 may be less than 1 μm or greater than 300 μm.

Lenses 110 may be formed as pre-molded structures that are attached to the layer 108, formed by applying a lens material on the layer 108 followed by molding the lens material and (optionally) curing the molded lens material. In another embodiment, however, the layer 108 and the lens 110 may be provided as an integral structure, e.g., as described in any of U.S. Patent App. Pub. Nos. 2012/0205694, 2012/0187430 or 2011/0031516, the contents of all of which are incorporated herein by reference in their entirety.

FIG. 2 is a schematic view illustrating one embodiment of an apparatus for singulating a component package from the die-package substrate assembly shown in FIG. 1.

In one embodiment, an apparatus such as apparatus 200 may be used to singulate the die-package substrate assembly 100. As exemplarily illustrated, the apparatus 200 may include a workpiece support 202 configured to support a workpiece such as the die-package substrate assembly 100, an external object 204 configured to exert a force on the die-package substrate assembly 100. The apparatus may further include a driving system 206 (e.g., a servo motor, a pneumatic actuator, a hydraulic actuator, or the like or a combination thereof, operative to move the external object 204 (e.g., which may be guided by a one or more rails, linkages, tracks, or the like or a combination thereof, not shown) along a direction indicated by double-headed arrow 208. Operation of the driving system 206 may be controlled by a controller 210.

Generally, the workpiece support 202 may include a support body 212 having a support surface 214 configured to support the die-package substrate assembly 100. A groove 216 may be formed in the support body 212, extending from the support surface 214. Generally, the location of the groove 216 at the support surface 208 may correspond to the location of the external object 204 relative to the support surface 214 and also to the location of a scribe line region within the die-package substrate assembly 100. The width, w, of the groove 216 may be selected or set based on the thickness, t1, of the substrate 102, the depth, d, to which the crack initiator 114a extends into the substrate 102, the material from which the substrate 102 is formed, the size of the LED die 106 adjacent to the scribe line region disposed over the groove 216, or the like or a combination thereof. Generally, however, the width, w, of the groove may be in a range from 0.2 mm to 2.0 mm. For example, the width, w, of the groove 216 may be greater than 0.5 mm, greater than 0.7 mm, greater than 1.0 mm, or greater than 1.2 mm. In another example, the width, w, of the groove 210 may be less than 1.8 mm. In still another example, the width, w, of the groove 216 may be 1.5 mm (or about 1.5 mm). It will be appreciated, however, that the width, w, of the groove 216 may be less than 0.2 mm or greater than 2.0 mm.

Generally, the external object 204 may include a contact surface 218 configured to mechanically contact the die-package substrate assembly 100 (e.g., at the portion “A” of the layer 108). In one embodiment, the contact surface 218 may be characterized as being relatively blunt or flat so that the external object 204 can compress the portion of the layer 108 (e.g., predominantly downwardly along the direction indicated by arrow 208) without splitting, parting or otherwise cutting the portion of the layer 108 substantially immediately after contacting the portion of the layer 108.

The driving system 206 is configured to move the external object 204 along the direction indicated by arrow 208 over a distance in a range from 100 mm to 200 mm (e.g., in a range from 120 mm to 170 mm) at a speed in a range of 5 mm/s to 30 mm/s (e.g., about 25 mm/s). In one embodiment, the driving system and the external object 204 are configured to physically contact the die-package substrate assembly 100 (e.g., at the portion of the layer 108) with a force capable of compressing the portion of the layer 108 at a sufficiently high strain rate to modify a mechanical property (e.g., decrease the ductility or malleability) of the portion of the layer 108. In another embodiment, however, the driving system and the external object 204 are configured to physically contact the die-package substrate assembly 100 (e.g., at the portion of the layer 108) with a force capable of compressing the portion of the layer 108 at a sufficiently low strain rate that does not modify the mechanical property (e.g., decrease the ductility or malleability) of the portion of the layer 108.

In one embodiment, the apparatus 200 may optionally include a temperature control system 220 configured to cool the aforementioned portion of the layer 108 disposed in a scribe line region of the die-package substrate assembly 100 to modify the mechanical property of the portion of the layer 108 as exemplarily described above (e.g., to decrease the ductility or malleability of the portion of the layer 108). Thus, the temperature control system 220 may include a coolant circulation line coupled to a heat exchanger, a thermoelectric cooler, or the like or a combination thereof. In the illustrated embodiment, the temperature control system 220 is thermally coupled to one or both of the workpiece support 202 and the external object 204. When thermally coupled to the workpiece support 202, the temperature control system 220 may indirectly remove heat from the portion of the layer 108 disposed in the scribe line region of the die-package substrate assembly 100, through the workpiece support 202. When thermally coupled to the external object 204, the temperature control system 220 may indirectly remove heat from the portion of the layer 108 disposed in the scribe line region of the die-package substrate assembly 100 through the external object 204. In another embodiment, however, the temperature control system 220 is not thermally coupled to either the workpiece support 202 or the external object 204. In such an embodiment, the temperature control system 220 is configured to directly remove heat from the portion of the layer 108 disposed in the scribe line region of the die-package substrate assembly 100. Operation of the temperature control system 220 may be controlled by the controller 212.

In another embodiment, the apparatus 200 may optionally include an alignment system 222 configured to adjust an orientation and/or position of one or more or all of the die-package substrate assembly 100, the workpiece support 202 and the external object 204 relative to one another to ensure that a scribe line region of the die-package substrate assembly 100 and one or both of the workpiece support 202 and the external object 204 are properly or adequately aligned with one another. Thus, the alignment system 222 may include one or more cameras, stages, motors, rollers, actuators, or the like or a combination thereof. Operation of the temperature control system 220 may be controlled by the controller 212.

Generally, the controller 212 can include operating logic (not shown) that defines various control functions, and may be in the form of dedicated hardware, such as a hardwired state machine, a processor executing programming instructions, and/or a different form as would occur to those skilled in the art. Operating logic may include digital circuitry, analog circuitry, software, or a hybrid combination of any of these types. In one embodiment, controller 212 includes a programmable microcontroller microprocessor, or other processor that can include one or more processing units arranged to execute instructions stored in memory (not shown) in accordance with the operating logic. Memory can include one or more types including semiconductor, magnetic, and/or optical varieties, and/or may be of a volatile and/or nonvolatile variety. In one embodiment, memory stores instructions that can be executed by the operating logic. Alternatively or additionally, memory may store data that is manipulated by the operating logic. In one arrangement, operating logic and memory are included in a controller/processor form of operating logic that manages and controls operational aspects of any component of the apparatus 200, although in other arrangements they may be separate.

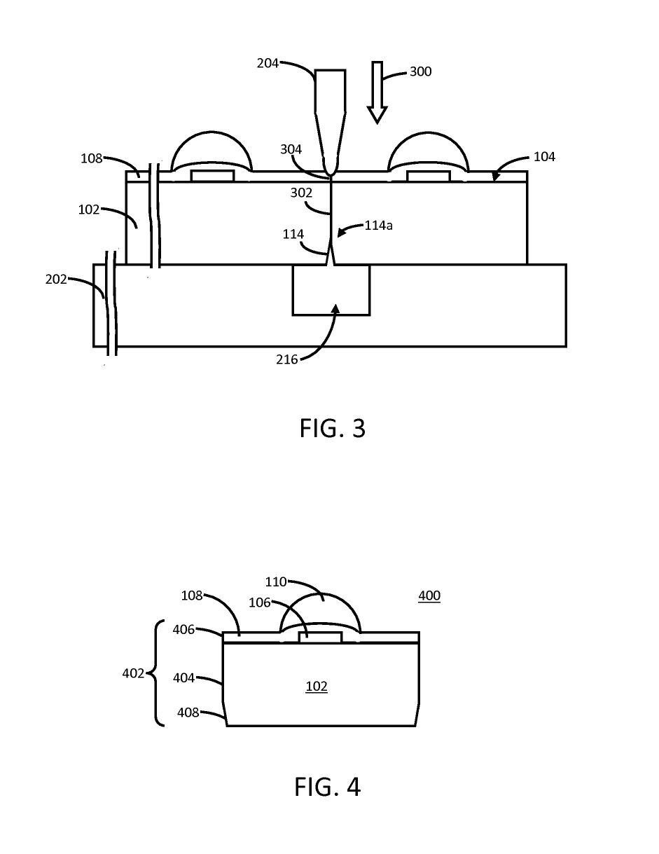

FIG. 3 is a side plan view schematically illustrating one embodiment of a process for singulating a component package from a die-package substrate assembly using the apparatus shown in FIG. 2.

To singulate a component package from the die-package substrate assembly 100, the die-package substrate assembly 100 is arranged on the support surface 214 of the support body 212 such that the portion of the layer 108 disposed in the scribe line region (e.g., between the two illustrated LED dies 106) of the die-package substrate assembly 100 is located over the groove 216. The driving system 206 is then operated to move the external object 204 toward the die-package substrate assembly 100 (e.g., along the direction indicated by arrow 300) so that the contact surface 218 physically contact the die-package substrate assembly 100 (e.g., at the portion of the layer 108). The external object 204 is further driven to impart a force on the die-package substrate assembly 100 at a location over the groove 216, which results in the generation of a bending moment within die-package substrate assembly 100 (e.g., including a region of the substrate 102 occupied by the crack initiator 114a). Stress within the region of the substrate 102 is concentrated at the crack initiator 114a, and the force imparted from the external object 204 propagates a crack 302 from the crack initiator 114a through the region of the substrate 102 to the first surface 104. Upon propagating the crack 302, the region of the substrate 102 may be fractured. Further, and depending on the configuration of the apparatus 200, the mechanical property of the portion of the layer 108 may be modified (e.g., such that the ductility of the portion of the layer 108 is decreased) either before or while a mechanical force is imparted to the portion of the layer 108 by the external object 204. Consequently, the portion of the layer 108 can be fractured (e.g., along a crack 304 propagated through the thickness of the portion of the layer 108). While not wishing to be bound by any particular theory, it is believed that the portion of the layer 108 can become fractured due to a force (e.g., a tensile force) imparted by the first surface 104 of the substrate 102 to the portion of the layer 108 just after the crack 302 propagates through the region of the substrate 102 to the first surface 104 (e.g., different portions of the substrate 102 on either side of the crack 302 may be driven apart from one another by the external object 204 immediate after the crack 302 propagates to the first surface 104), due to a force imparted by a crack tip of the crack 302 upon reaching the first surface 104, or the like or a combination thereof.

FIG. 4 is a side plan view schematically illustrating one embodiment of a component package singulated in the process shown in FIG. 3.

By performing the above-described process of fracturing the substrate 102 and the portion of the layer 108, the die-package substrate assembly 100 may be fractured along a scribe line extending between adjacent LED dies 106. The process may be repeated as desired (e.g., by moving one or more or all of the die-package substrate assembly 100, the workpiece support 202 and the external object 204 relative to one another) to fracture the die-package substrate assembly 100 along one or more other scribe lines. Upon fracturing the die-package substrate assembly 100 in the manner described above, a component package, such as LED package 400 shown in FIG. 4, may be singulated from the die-package substrate assembly 100.

Referring to FIG. 4, the LED package 400, singulated from the die-package substrate assembly 100 according to embodiments of the present invention may be characterized as including the aforementioned substrate 102 and layer 108, as well as an LED die 106 and a lens 110. Although the LED package 400 is illustrated as including only one LED die 106, it will be appreciated that the singulated LED package 400 may include multiple LED die 106. Although the LED package 400 is illustrated as including only one lens 110, it will be appreciated that the singulated LED package 400 may include multiple lenses 110.

Generally, the LED package 400 has an edge surface 402 that includes a first surface portion 404 and a second surface portion 406. The first surface portion 404 corresponds to a surface created within the substrate 102 due to fracturing of the substrate 102 (e.g., upon propagating the crack 302, as discussed with respect to FIG. 3) during the singulation process. Thus, the first surface portion 404 may have a texture corresponding to the nature by which the substrate 102 was fractured. The second surface portion 406 corresponds to a surface created within the layer 108 due to fracturing of the portion of the layer 108 (e.g., upon propagating the crack 304, as discussed with respect to FIG. 3) during the singulation process. Thus, the second surface portion 406 may have a texture corresponding to the nature by which the portion of the layer 108 was fractured. In embodiments where the crack initiator 114a is formed at the tip of the trench 114, the edge surface 402 may further include a third surface region corresponding to a sidewall of the trench 114. Generally, the thickness of the second edge portion 406 may correspond to the thickness of the portion of the layer 108 from which it was formed. Thus, the thickness of the second edge portion 406 may be less than 200 μm. For example, the thickness of the second edge portion 406 can be less than 150 μm, less than 100 μm, or less than 50 μm. In other embodiments, however, the thickness of the second edge portion 406 may be less than 1 μm or greater than 300 μm.

Although the process of singulating the die-package substrate assembly 100 has been described above as involving the mechanical force imparted by a relatively blunt or flat contact surface 218 onto a portion of the die-package substrate assembly 100 (e.g., at the portion of the layer 108), it will be appreciated that the contact surface 218 may be characterized as being relatively sharp so that the external object 204 can split, part or otherwise cut portion of the layer 108 substantially immediately after contacting the portion of the layer 108.

Although the process of singulating the die-package substrate assembly 100 has been described above as involving the mechanical contact by a single external object 204 having a single, relatively blunt or flat contact surface 218, it will be appreciated that the external object 204 may include multiple distinct, spaced apart contact surfaces, any of which may be relatively blunt or relatively sharp to physically contact different areas within the same portion of the layer 108 (e.g., on opposite sides of a common crack initiator, on the same side of a crack initiator, or the like or a combination thereof). It will also be appreciated that the apparatus 200 may include multiple external objects, each having one or more contact surfaces configured to physically contact different areas within the same portion of the layer 108.

Although the process of singulating the die-package substrate assembly 100 has been described above as involving the fracture of the substrate 102 and the portion of the layer 108 upon performing a single, continuous mechanical impact event (e.g., in which the external object is driven to physically the die-package substrate assembly 100 (e.g., at the portion of the layer 108), it will be appreciated that the substrate 102 and the portion of the layer 108 may be fractured in separate mechanical impact events. For example, the portion of the layer 108 may be fractured using an external object having a relatively sharp impact surface and the substrate 102 may be fractured using an external object having a relatively blunt impact surface, either before or after the portion of the layer 108 is fractured using the external object having the relatively sharp impact surface.

Although the temperature control system 220 has been described above as being configured to cool the portion of the layer 108, it will be appreciated that the temperature control system 220 may alternatively or additionally be configured to heat the portion of the layer 108 to modify the mechanical property of the portion of the layer 108 as exemplarily described above (e.g., to increase the ductility or malleability of the portion of the layer 108). Increasing the ductility or malleability of the portion of the layer 108 may facilitate fracture of the portion of the layer 108 by splitting, parting, or other cutting in a manner that results in no (or substantially no) material removal from the portion of the layer 108. In one embodiment, the temperature control system 220 may include a resistive heating element, an infrared heat gun, or the like or a combination thereof. In the illustrated embodiment, the temperature control system 220 is thermally coupled to one or both of the workpiece support 202 and the external object 204. When thermally coupled to the workpiece support 202, the temperature control system 220 may indirectly add heat to the portion of the layer 108 through the workpiece support 202. When thermally coupled to the external object, the temperature control system 220 may indirectly add heat to the portion of the layer 108 through the external object 204. In another embodiment, however, the temperature control system 220 is not thermally coupled to either the workpiece support 202 or the external object 204. In such an embodiment, the temperature control system 220 is configured to directly add heat to the portion of the layer 108.

The foregoing is illustrative of embodiments of the invention and is not to be construed as limiting thereof. Although a few example embodiments of the invention have been described, those skilled in the art will readily appreciate that many modifications are possible in the example embodiments without materially departing from the novel teachings and advantages of the invention. In view of the foregoing, it is to be understood that the foregoing is illustrative of the invention and is not to be construed as limited to the specific example embodiments of the invention disclosed, and that modifications to the disclosed example embodiments, as well as other embodiments, are intended to be included within the scope of the appended claims. The invention is defined by the following claims, with equivalents of the claims to be included therein.

What is claimed is:

1. A method, comprising:
providing a substrate with a plurality of semiconductor devices disposed on a first side the substrate, having a layer disposed on the first side of the substrate, wherein the layer is formed of a material that is less brittle than the substrate;
compressing a portion of the layer along a line between devices in the plurality of semiconductor devices such that the portion of the layer has a modified mechanical property;
propagating a crack through the substrate along the line; and
fracturing the portion of the layer having the modified mechanical property along the line.

2. The method of claim 1, wherein the semiconductor devices in the plurality of semiconductor devices are selected from the group consisting of laser diodes and light-emitting diodes.

3. The method of claim 1, wherein the layer overlies the plurality of semiconductor devices.

4. The method of claim 1, including a plurality of lenses disposed over the plurality of semiconductor devices, and where the layer is disposed between the plurality of lenses and the plurality of semiconductor devices.

5. The method of claim 4, wherein the layer comprises a phosphor.

6. The method of claim 1, wherein the substrate includes at least one material selected from the group consisting of alumina and aluminum nitride.

7. The method of claim 1, further comprising:
forming a crack initiator within the substrate; and
propagating the crack from the crack initiator to the first side of the substrate.

8. The method of claim 7, wherein forming the crack initiator comprises directing at least one laser pulse onto the substrate.

9. The method of claim 1, further comprising:
providing a workpiece support including a support body having a support surface and a groove extending from the support surface;
supporting the substrate on a second side on the support surface such that the line overlies the groove.

10. A method, comprising:
providing a workpiece including a substrate and a layer disposed on a surface of the substrate;
subjecting the workpiece to a mechanical stress at a location relatively proximate to the layer and relatively distant from the substrate;
fracturing a portion of the layer proximate to the location of mechanical stress; and
propagating a crack through a region of the substrate.

11. The method of claim 10, wherein the substrate includes at least one object located on a first surface, the at least one object including at least one selected from the group consisting of a semiconductor device and a micro-electro-mechanical system (MEMS).

12. The method of claim 11, wherein the at least one object includes at least one semiconductor device selected from the group consisting of a laser diode, a light-emitting diode, a field effect transistor, an integrated circuit, a micro-processor, a hall-effect sensor, a charge-coupled device and a random-access memory.

13. The method of claim 11, wherein at least a portion of the layer is disposed over the at least one object.

14. The method of claim 10, wherein the substrate includes at least one material selected from the group consisting of alumina and aluminum nitride.

15. The method of claim 10, wherein the substrate is a semiconductor substrate.

16. The method of claim 10, wherein the substrate includes at least one material selected from the group consisting of silicon, silicon carbide, silicon-germanium alloy, gallium nitride, gallium arsenide, indium gallium nitride, aluminum gallium arsenide, indium phosphide and zinc selenide.

17. The method of claim 10, wherein the substrate is a ceramic substrate.

18. The method of claim 10, wherein the substrate is a glass substrate.

19. The method of claim 10, wherein the substrate is a metallic substrate.

20. The method of claim 10, wherein the layer is a polymeric layer.

21. The method of claim 10, wherein the layer includes at least one material selected from the group consisting of silicone, polyurethane, polymethyl methacrylate, polycarbonate and epoxy.

22. The method of claim 10, wherein the layer is a metallic layer.

23. The method of claim 10, wherein subjecting the portion of the layer to a mechanical stress comprises subjecting the portion of the layer to compression.

24. The method of claim 10, further comprising:
forming a crack initiator within the substrate; and
propagating the crack from the crack initiator to the surface.

25. The method of claim 27, wherein forming the crack initiator comprises directing at least one laser pulse onto the substrate.

26. The method of claim 10, further comprising:
providing a workpiece support including a support body having a support surface and a groove extending from the support surface; and
supporting a second surface on the support surface such that the portion of the substrate extends over the groove.

27. A method, comprising:
providing a workpiece including:
a package substrate;
a plurality of objects disposed on a first surface of the package substrate; and
a layer disposed on the first surface of the substrate between the plurality of objects, wherein the layer is formed of a material having a mechanical property;
modifying the mechanical property of a portion of the layer;
deforming a region of the package substrate proximate to the portion of the layer; and
fracturing the portion of the layer having the modified mechanical property at a location proximate to the deformed region of the package substrate.

28. An article produced by a process according the method recited in claim 1.

29. An article produced by a process according the method recited in claim 10.

30. An article produced by a process according the method recited in claim 27.

31. A light-emitting diode (LED) package, comprising:
a ceramic package substrate;
an LED die disposed on a surface of the ceramic package substrate; and
an encapsulant layer disposed on the surface of the ceramic package substrate and overlapping at least a portion of the LED die, wherein a sidewall of the encapsulant layer has a texture formed by a fracturing process.

32. The LED package of claim 31, wherein the ceramic package substrate includes at least one material selected from the group consisting of alumina and aluminum nitride.

33. The LED package of claim 31, wherein the encapsulant layer includes at least one material selected from the group consisting of silicone, polyurethane, polymethyl methacrylate, polycarbonate and epoxy.

34. The LED package of claim 31, wherein the encapsulant layer includes a phosphor material.
